(19) United States
(12) Patent Application Publication
(10) Pub. No.: US 2009/0278212 A1
(43) Pub. Date: Nov. 12, 2009

(54) Integrated Device

(76) Inventors: Makoto Ishida, Aichi (JP); Kazuaki Sawada, Aichi (JP); Daisuke Akai, Aichi (JP); Keisuke Hirabayashi, Aichi (JP)

Correspondence Address: FROMMER LAWRENCE & HAUG, 745 FIFTH AVENUE- 10TH FL., NEW YORK, NY, 10151, US

(21) Appl. No.: 11/921,481

(22) PCT Filed: Jun. 2, 2006
(86) PCT No.: PCT/JP2006/311127

§ 371 Date: Feb. 27, 2009

(30) Foreign Application Priority Data
Jun. 4, 2005 (JP) 2005-192798

(51) Int. Cl. H01L 25/16; H01L 21/306

(52) U.S. Cl. 257/414; 438/694; 257/E25.029; 257/E21.215

(57) ABSTRACT

An integrated device including a sensor and the like formed on a γ-alumina layer epitaxially grown on a silicon substrate is provided at low cost. This integrated device includes: a silicon substrate; a first function area formed on a γ-alumina film epitaxially grown on a portion of the silicon substrate; a second function area formed on an area of the silicon substrate other than an area where the γ-alumina film is grown; and wiring means for connecting the first function area with the second function area.

### TECHNICAL FIELD

The present invention relates to an integrated device.

### BACKGROUND ART

Patent Document 1 and Patent Document 2 respectively describes examples where a γ-alumina layer is epitaxially grown on a silicone substrate, and a pyroelectric infrared sensor or an ultrasonic sensor is formed using the γ-alumina layer.

Patent Document 3 discloses an infrared detecting circuit including a sensor and its switching circuit on one silicon substrate. In this detecting circuit, a silicon oxide film is formed on the silicon substrate, and the sensor and the switching circuit are formed using the silicon oxide film as a base, that is, as a common insulating film.

The infrared detecting circuit described in Patent Document 3 is constituted by linking a capacitor and a transistor for infrared detection with each other, and its output signal is processed by an external signal processing circuit.

[Patent Document 1] JP-A-2004-281742

[Patent Document 2] JP-A-1997-89651

[Patent Document 3] JP-A-1999-271141

### DISCLOSURE OF THE INVENTION

### Problem to be Solved by the Invention

In recent years, a sensor is required to have various properties. However, there are some cases where the silicon oxide film-based sensor cannot sufficiently meet such a request.

To overcome this problem, as is disclosed in Patent Document 1, there are some cases where a γ-alumina layer-based sensor is used. Since this sensor is built on one substrate, in order to allow it to function as a sensor, it is required to assemble the sensor with a discrete element for a peripheral circuit. In thus-structured integrated device, most of the manufacturing cost is spent for this assembly.

### Means for Solving the Problem

The present invention has been made to solve the problem described above.

Specifically, the first aspect of the present invention is defined as follows.

An integrated device, including:

a silicon substrate;

a first function area formed on a γ-alumina film epitaxially grown on a portion of the silicon substrate;

a second function area formed on an area of the silicon substrate other than an area where the γ-alumina film is grown; and

wiring means for connecting the first function area with the second function area.

According to thus-structured integrated device, a γ-alumina film is epitaxially grown on the silicon substrate. The first function area can be formed by use of this γ-alumina film. On the other hand, on the area of the silicon substrate having no γ-alumina film, a second function area can be formed. As is defined in a second aspect of the present invention, a sensor is employed as the first function area, and a signal processing circuit (peripheral circuit) for the sensor is formed as a second function area. Then, by connecting the sensor with the signal processing circuit via wiring means, it becomes possible to incorporate two functions (for example, a sensor and its peripheral circuit) into a single silicon substrate. This eliminates the need of assembly operation, thereby achieving reduction in manufacturing cost.

The sensor of the integrated device of the present invention is formed by use of the γ-alumina film epitaxially grown on the silicon substrate as a base. Therefore, the sensor has a property totally different from that of a sensor formed by use of a silicon oxide film as a base.

A third aspect of the present invention is defined as follows.

Specifically, in the integrated circuit defined in the first or second aspect, a level of a first surface of an area of the silicon substrate on which the first function area is formed is higher than a level of a second surface of an area of the silicon substrate on which the second function area is formed.

According to the third aspect of the present invention, the first area and the second area are clearly determined. Therefore, the arrangement of the circuit and the like can be easily checked.

When the level of the first area is differ from the level of the second area on the silicon substrate, the distance between the two levels becomes longer than the case where the two levels are even. This is especially preferable in the case as is defined in a fifth aspect of the present invention where the first function area contains a material having high diffusivity in the silicon substrate such as Pb, from the viewpoint of more reliably eliminating the influence of the material.

The difference in height between the first surface and the second surface on the silicon substrate is preferably 0.1 to 1.0 μm as is defined in a fourth aspect of the present invention. If the difference therebetween is less than 0.1 μm, this is a state where a layer doped with aluminum remains on the second surface of the silicon substrate as will be described later. Contrarily, if the difference therebetween exceeds 1.0 μm, this is inconvenient for forming metal wiring. Therefore, both of them are not preferable.

Here, it is preferable that the γ-alumina layer is in the form of a thin film in relation to heat release and the like. According to the studies made by the present inventors, it is preferable film thickness of the γ-alumina layer in the integrated circuit is 10 to 100 nm.

In the structure where the γ-alumina layer is made into the form of a thin film as described above, there is a possibility that the material contained in the first function area easily diffuses into the silicon substrate. For example, when a PZT (lead zirconate titanate) layer is used for an infrared sensor, the lead contained in this layer diffuses through the γ-alumina layer into the silicon substrate. If this lead diffuses into the second function area, there is a possibility that the lead adversely affects the circuit formed in the second function area.

On the silicon substrate, as a result that the level of the surface of the first area on which the first function area is formed and the level of the surface of the second area on which the second function area is formed are not even, the distance from the first area to the second area becomes longer. In this manner, even if Pb or the like diffuses from the first area, the influence thereof is hard to appear on the surface of the second area.

Another aspect of the present invention relates to a method for manufacturing the integrated device described above, and is defined as follows.

Specifically, the method for manufacturing an integrated device, includes:

a step of epitaxially growing a γ-alumina film on a surface of a silicon substrate;

a first etching step of removing a portion of the γ-alumina film to expose the silicon substrate;

a second etching step of removing a surface of the silicon substrate exposed as a result of the first etching step;

a step of forming a first function area on the γ-alumina film;

a step of forming a second function area on the silicon substrate exposed as a result of the second etching step; and

a step of wiring the first function area with the second function area.

According to the manufacturing method structured as described above, the integrated device described in the first to fourth aspects already described above can be easily manufactured.

In the description above, in the second etching step, it is preferable to remove a portion of the silicon substrate containing aluminum which diffused thereinto at the time when the γ-alumina film was formed. When the γ-alumina film is epitaxially grown, aluminum diffuses over the surface of the silicon substrate. Since aluminum is a p-type dopant to silicon, the conductivity of the surface of the silicon substrate into which aluminum has diffused becomes p-type. Such a highly doped silicon substrate is not suitable for building a circuit thereon by doping various kinds of dopants. To solve this problem, it is preferable to remove the surface portion of the silicon substrate into which the aluminum has diffused, so as to expose the silicon substrate with conductivity suitable for building the circuit thereon.

As a result of the studies made by the present inventors, it has been found that aluminum diffuses from the γ-alumina film into the surface of the silicon substrate to the depth of about 0.1 to about 1.0 μm. Therefore, by removing the portion with this depth in the second etching step, it is possible to obtain the surface of the silicon substrate suitable for forming the second function area such as a circuit.

As a first etching step for removing the γ-alumina film, it is preferable to employ anisotropic etching such as Inductively Coupled Plasma Reactive Ion Etching (ICP-RIE). Alternatively, the γ-alumina film may also be removed by a method such as an etching where Si ion is doped into the alumina film to turn the nature of the alumina film into amorphous, and then the film is etched by a chemical solution containing fluorinated acid.

As a second etching process to be carried out after the removal of the γ-alumina film, it is preferable to employ RIE. This is because the etched surface of the silicon substrate is kept smooth, and thus, the formation of the second function area becomes easy. Alternatively, the surface of the silicon substrate may be removed by a method such as an etching where an oxide film is formed thermally, and then the oxide film is etched by a solution containing fluorinated acid.

The integrated device defined in the first and second aspects of the present invention may alternatively be obtained in the following manufacturing method.

Specifically, the method for manufacturing an integrated device, comprises:

a step of forming a second function area on a portion of a silicon substrate;

a step of protecting the second function area by a second protective film and epitaxially growing a γ-alumina film on the surface of the silicon substrate;

a step of forming a first function area on the γ-alumina film;

a step of protecting the first function area by a first protective film and peeling the second protective film; and
a step of peeling the first protective film and wiring the first function area with the second function area.

### BRIEF DESCRIPTION OF THE DRAWINGS

FIG. 1 is a cross-sectional view showing a structure of an integrated device according to a first embodiment of the present invention.

FIG. 2 is a plan view thereof.

FIG. 3 is a flow chart illustrating a method for manufacturing the integrated device of the first embodiment.

FIG. 4 is a schematic view of a method for manufacturing the same.

FIG. 5 is a cross-sectional view showing a structure of the integrated device according to the second example of the present invention.

FIG. 6 is a flow chart illustrating a method for manufacturing the integrated device of the second example.

FIG. 7 is a schematic view of a method for manufacturing the same.

### DESCRIPTION OF THE REFERENCE NUMERALS

1, 101: Integrated device
3: Silicon substrate
10: Sensor
11, 35, 110: γ-alumina film
20: Signal processing circuit
10A: First area
20A: Second area

### BEST MODE FOR CARRYING OUT THE INVENTION

### First Example

Next, an example of the present invention will be described.

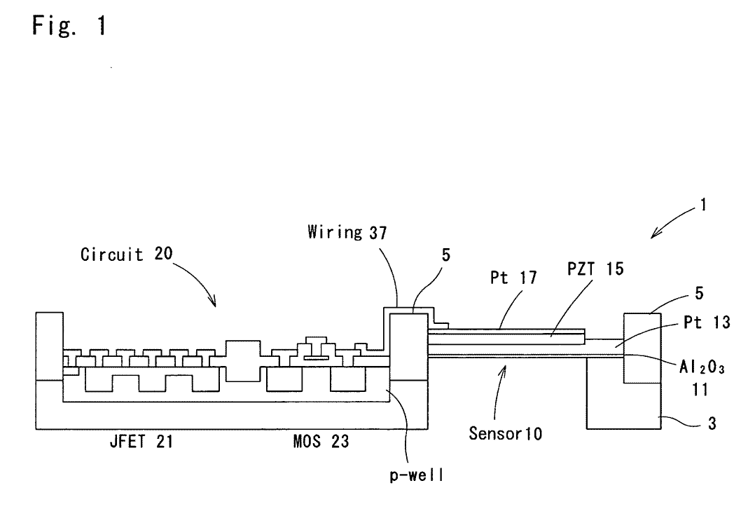

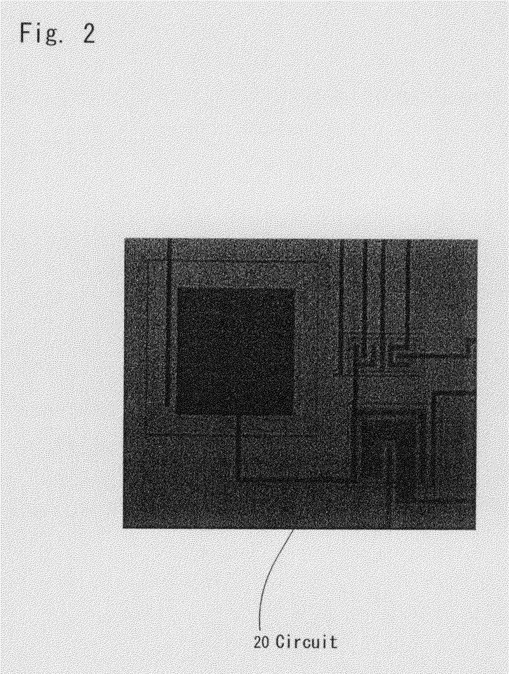

FIG. 1 is a cross-sectional view showing a structure of an integrated device 1 according to an example of the present invention. FIG. 2 is a plan view thereof.

The integrated device 1 of this example includes a sensor 10 as a first function area, and a signal processing circuit 20 as a second function area. These two areas 10, have a common silicon substrate 3 and are insulated from each other via an insulating area 5 made of silicon oxide.

The sensor area 10 includes a γ-alumina layer 11 as a base that is epitaxially grown on the silicon substrate 3, a platinum layer 13, a ferroelectric material layer 15, and another platinum layer 17 laminated on one another in this order, and thus constitutes a pyroelectric element.

The structure of the sensor 10 may be optionally selected on the assumption that the γ-alumina layer 11 is employed as a base.

In this example, a part of the silicon substrate in the sensor 10 is removed by etching.

The signal processing circuit 20 is formed with a JFET 21 and a MOS 23 by a usual method. The signal processing circuit 20 may include an arbitrary circuit built thereon by an arbitrary method.

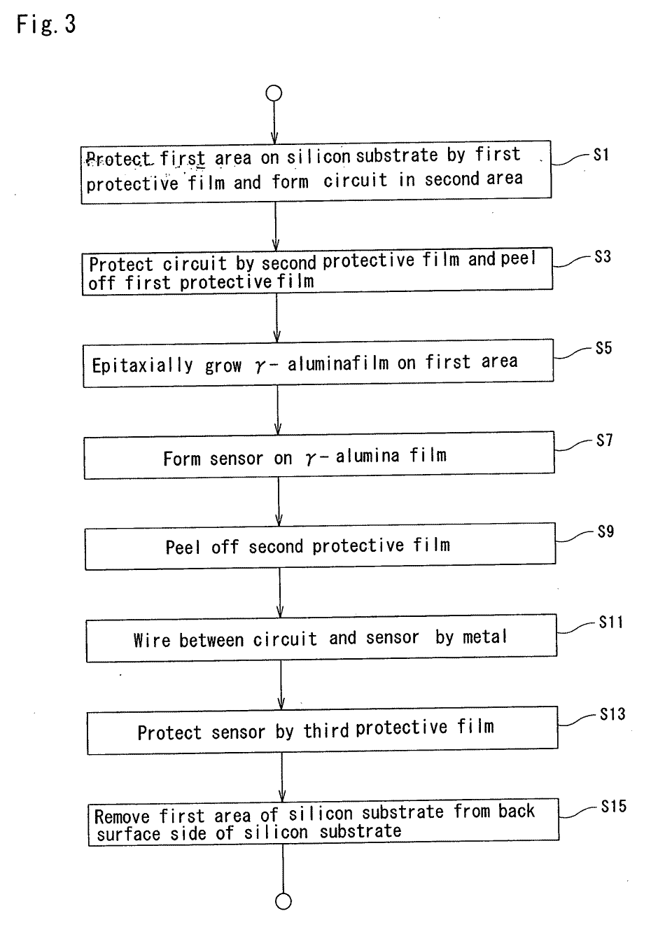

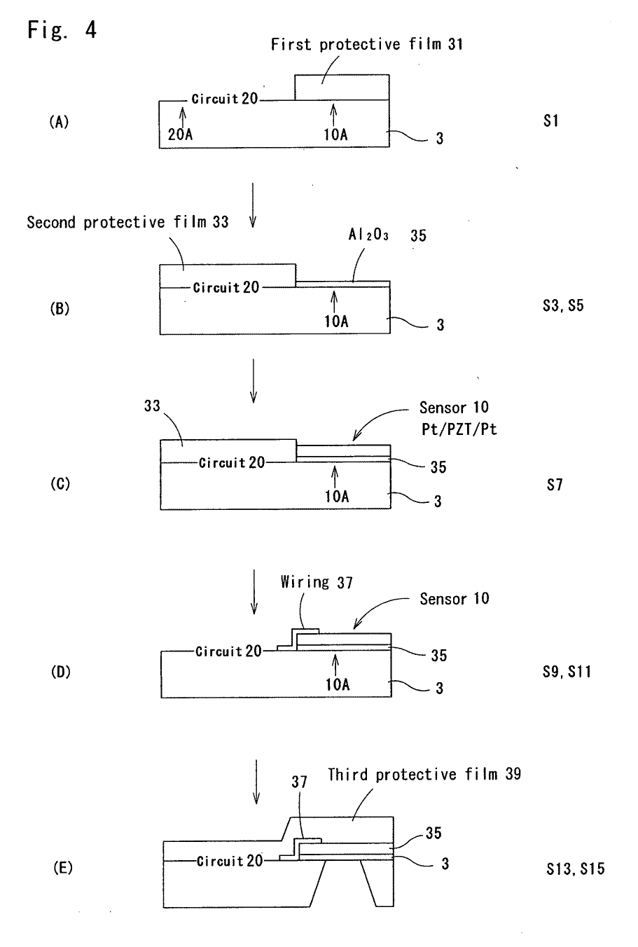

Next, a method for manufacturing the integrated device 1 shown in FIG. 1 will be illustrated with reference to the flow chart of FIG. 3 and FIG. 4.

In Step 1, an area on the silicon substrate 3 on which the sensor 10 is to be formed (a first area 10A) is covered with a first protective film 31 (see FIG. 4A). As the first protective film, an oxide film may be used, for example.

Next, a circuit 20 is formed on the exposed area of the silicon substrate (a second area 20A) by a generally employed method.

In Step 3 (see FIG. 4(B)), the circuit 20 is covered with a second protective film 33, whereas the first protective film 31 is removed. In this case, as the second protective film 33, an oxide film may be employed.

Subsequently, in Step 5, a γ-alumina layer 35 is epitaxially grown on a first area 10A exposed as a result that the first protective film 31 has been removed. The conditions of the epitaxial growth can be realized by, for example, setting a growth temperature to 900 to 1000° C. in chemical vapor deposition using TMA gas and oxygen gas. The film thickness of the γ-alumina layer 35 is preferably 10 nm to 100 nm.

In Step 7 (see FIG. 4(C)), a sensor 10 is formed on the γ-alumina layer 35. In this example, a platinum layer is sputtered on the γ-alumina layer 35, and a sol-gel PZT is applied on the platinum layer and is hardened. Then, another platinum layer is sputtered thereon. Each layer is etched into a predetermined shape by photolithography.

In Step 9 (see FIG. 4(D)), the second protective film is removed by RIE or etching with a chemical solution, and a metallic wiring 37 is patterned (Step 11). The wiring 37 may be made of aluminum or copper.

In Step 13, at least the sensor 10 is protected by a third protective film 39 (material: an oxide film or nitride film). In this state, a predetermined portion on the first area 10A is removed by etching carried out from the back surface side of the silicon substrate 3 (see Step 15, FIG. 4(E)).

After that, the third protective film 39 is removed, thereby obtaining the integrated device 1 shown in FIG. 1.

### Second Example

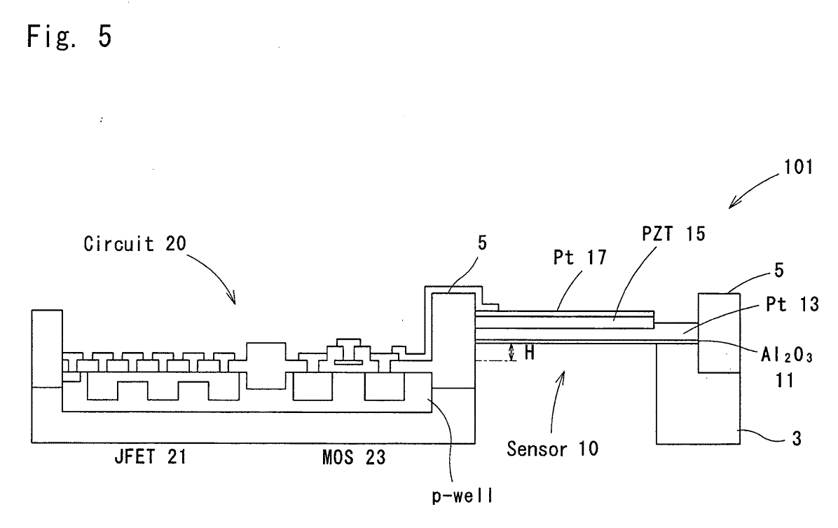

FIG. 5 shows an integrated device 101 according to a second example of the present invention. The same constituent elements as of FIG. 1 are denoted by the same reference numerals, and their descriptions will be omitted.

In the integrated device 101 of this example, there is provided a height difference H between the surface of the silicon substrate 3 on which the sensor 10 is to be formed and the surface of the silicon substrate 3 on which the signal processing circuit 20 is to be formed.

By providing the height difference H described above, as compared with the example shown in FIG. 1 without height difference, the distance from the PZT 15 including Pb having diffusivity to the circuit 20 becomes longer. Owing to this structure, the influence of this Pb to the area of the circuit 20 can be eliminated as much as possible.

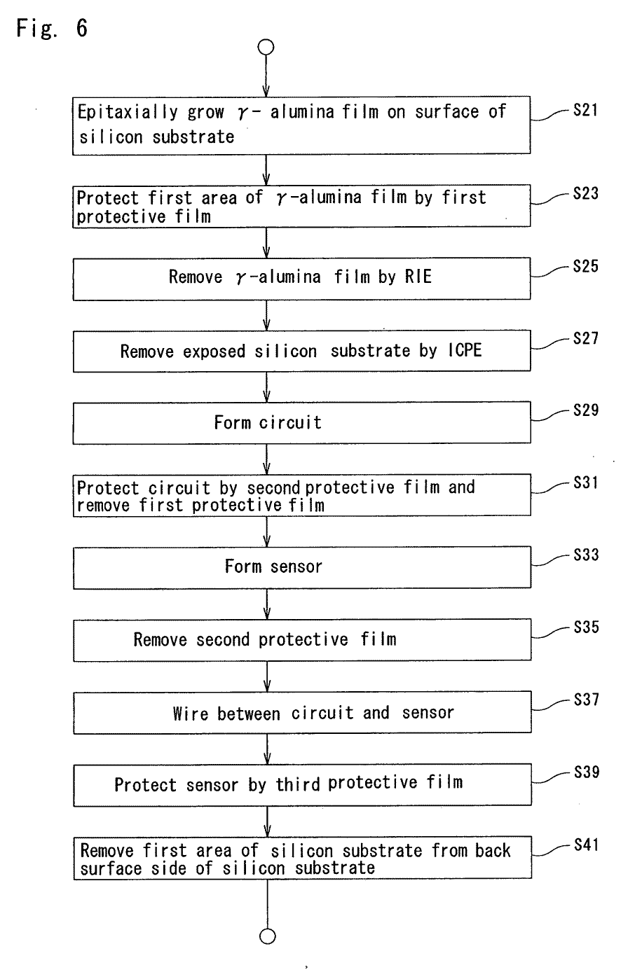

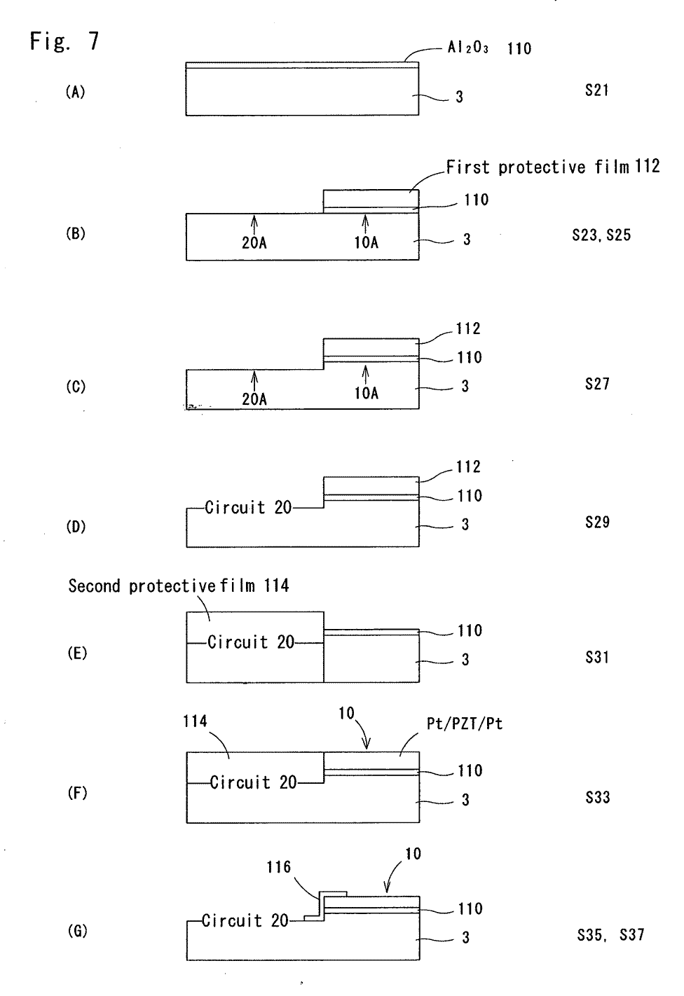

A method for manufacturing the integrated device 101 shown in FIG. 5 will be illustrated with reference to the flow chart of FIG. 6 and FIG. 7.

In Step 21, a γ-alumina layer 110 is epitaxially grown over the entire surface of a silicon substrate 3. The γ-alumina layer 110 is grown under the conditions where the growth temperature is set to 900 to 1000° C. in chemical vapor deposition using TMA gas and oxygen gas. Further, the film thickness of the γ-alumina layer 110 is set to 10 nm to 100 nm.

In Step 23, an area of the γ-alumina layer 110 corresponding to a first area 10A of the silicon substrate is protected by a first protective film 112. The first protective film 112 may be made of silicon nitride. Specifically, a silicon nitride film is grown over the entire area of the γ-alumina layer 110 by a method such as sputtering. In Step 25, the area 10A is formed by photolithography and silicon nitride layer and the γ-alumina layer 110 are etched. At this time, as an etching method, it is preferable to employ ICP-RIE that exhibits high etching rate.

In Step 27 (see FIG. 7(C)), a second area 20A of the silicon substrate exposed in Step 25 is etched by RIE. As a result of this, the second area 20A of the silicon substrate can be smoothened. Further, aluminum is in a diffusing state over the second area 20 and results in changing the conductivity of the second area 20 (i.e. the nature of the second area 20 is changed into p-type). By etching the surface of the second area 20A in this Step 27, the portion of the second area 20A whose conductivity has changed is removed, so that the original property of the silicon substrate 3 becomes available.

In Step 29, a circuit 20 is built on thus obtained second area having the original property of the silicon substrate 3 (see FIG. 7(D)).

In Step 31, as shown in FIG. 7(E), the circuit 20 is protected by a protective film 114, whereas the first protective film 112 is removed by etching to expose the γ-alumina layer 110. In Step 33, platinum/PZT/platinum is laminated on one another on the surface of the exposed γ-alumina layer 110 in this order in the same process as of example 1, so as to form a sensor 20.

In Step 35, the second protective film 114 is removed by etching. Then, in Step 37, a metal wiring 116 is formed between the sensor 10 and the circuit 20 (see FIG. 7(G)). In Step 39, at least the sensor 10 is protected by a third protective film (material: an oxide film or nitride film). In this state, a predetermined portion of the first area is removed by etching carried out from the back surface side of the silicon substrate 3 (see Step 41).

After that, the third protective film is removed, thereby obtaining the integrated device 101 shown in FIG. 5.

1-14. (canceled)

15. An integrated device, comprising:
a silicon substrate;
a first function area formed on a γ-alumina film epitaxially grown on a portion of the silicon substrate;
a second function area formed on an area of the silicon substrate other than an area where the γ-alumina film is grown; and
a wire for connecting the first function area with the second function area,
wherein a level of a first surface of an area of the silicon substrate on which the first function area is formed is higher than a level of a second surface of an area of the silicon substrate on which the second function area is formed.

16. The integrated device according to claim 15, wherein a sensor is formed in the first function area, and a signal processing circuit for the sensor is formed in the second function area.

17. The integrated device according to claim 15, wherein the difference in height between the first surface and the second surface is 0.1 to 1.0 μm.

18. The integrated device according to claim 17, wherein the first function area contains a material having high diffusivity into the silicon substrate.

19. The integrated device according to claim 18, wherein the material having high diffusivity is Pb or its compound.

20. The integrated device according to claim 19, wherein the first function area contains lead zirconate titanate.

21. The integrated device according to claim 17, wherein a sensor is formed in the first function area, and a signal processing circuit for the sensor is formed in the second function area.

22. A method for manufacturing an integrated device, comprising:
a step of epitaxially growing a γ-alumina film on a surface of a silicon substrate;
a first etching step of removing a portion of the γ-alumina film to expose the silicon substrate;
a second etching step of removing a surface of the silicon substrate exposed as a result of the first etching step;
a step of forming a first function area on the γ-alumina film;
a step of forming a second function area on the silicon substrate exposed as a result of the second etching step; and
a step of wiring the first function area with the second function area.

23. The manufacturing method according to claim 22, wherein a portion of the silicon substrate containing aluminum diffused at the time of forming the γ-alumina film is removed in the second etching step.

24. The manufacturing method according to claim 23, wherein 0.1 to 1.0 μm in thickness of the surface of the silicon substrate is removed in the second etching step.

25. The manufacturing method according to claim 22, wherein the first etching step carries out Inductively Coupled Plasma Reactive Ion Etching (ICP-RIE), whereas the second etching step carries out Reactive Ion Etching (RIE).

26. The manufacturing method according to claim 22, wherein the second function area is formed after the γ-alumina film is protected by a first protective film, and the first protective film is peeled after the second function area is protected by a second protective film and the first function area is formed on the γ-alumina film, and the second protective film is peeled and the first function area is wired with the second function area.
